(19) United States
(12) Patent Application Publication
(10) Pub. No.: US 2024/0343143 A1
(43) Pub. Date: Oct. 17, 2024

(54) CHARGING DEVICE AND CHARGING SYSTEM THEREOF

(71) Applicant: KENMEC MECHANICAL ENGINEERING CO., LTD., Taipei City (TW)

(72) Inventors: Feng-Jung YANG, Taipei City (TW); Fei-Jung HUANG, Taipei City (TW)

(21) Appl. No.: 18/632,337

(22) Filed: Apr. 11, 2024

Related U.S. Application Data
(60) Provisional application No. 63/495,555, filed on Apr. 12, 2023.

(30) Foreign Application Priority Data
Nov. 29, 2023 (TW) 112146363

(51) Int. Cl. B60L 53/31; B60L 53/16; H02J 7/00; H05K 7/20

(52) U.S. Cl. CPC B60L 53/31; B60L 53/16; H02J 7/0042; H05K 7/20927

(57) ABSTRACT

The present disclosure is related to a charging device and a charging system thereof. The charging system includes a plurality of sensing units, a charging connector and a charging device. The charging device is communicatively connected to the plurality of sensing units. The charging device is connected to the charging connector through a dielectric liquid pipeline. The charging device is used to receive at least one sensing signal from the sensing units, and based on the at least one sensing signal, the charging device executes a temperature pre-adjustment procedure on the charging device and the charging connector through the dielectric liquid pipeline before a charging procedure being executed. Therefore, the temperatures of the charging device and the charging connector are adjusted by the temperature pre-adjustment procedure.

### CROSS-REFERENCE TO RELATED APPLICATIONS

This application claims the priority benefit of U.S. provisional patent application No. 63/495,555, filed Apr. 12, 2023 and Taiwan Patent Application Serial Number 112146363, filed on Nov. 29, 2023, the full disclosure of which is incorporated herein by reference.

### TECHNICAL FIELD OF THE INVENTION

The present disclosure relates to a charging device and a charging system, and specifically, to a charging device and a charging system with temperature adjustment function.

### DESCRIPTION OF THE RELATED ART

A charging pile is a power supply equipment, charging pile which is equipped with at least one charging gun and is connected to the electric vehicle through the charging gun to provide electric energy to the electric vehicle.

Generally, in order to provide the electric energy required for charging electric vehicles, the charging pile is configured to perform an energy conversion (i.e., convert the electric currents from Alternating Current (AC) to Direct Current (DC)) when charging electric vehicles, and it causes a large amount of heat energy generated in the charging pile. At the same time, since the electric energy from the charging pile is transmitted to the charging gun through the power cable, the heat energy will be generated on the power cable and the charging gun during the power transmission process. The above-mentioned heat energy causes the electronic components in the charging pile and charging gun to operate at high temperature that affecting the lifetime and reliability of the electronic components.

Moreover, in areas with low temperature, the performance or the structure of the electronic components in the charging pile and the charging gun may be damaged due to low temperature. Thus, the lifetime and reliability of the electronic components also be affected by the low temperature.

Therefore, it is necessary to prevent the electronic components in the charging pile and the charging gun from operating at unexpected temperatures.

### SUMMARY OF THE INVENTION

The embodiment of the present disclosure provides a charging device and a charging system, which can execute a temperature pre-adjustment procedure on the charging device and a charging connector through a dielectric liquid pipeline before a charging procedure being executed by the charging device in order to cooling or heating the charging device and the charging connector. Therefore, the charging device and the charging connector can operate at an appropriate temperature to prevent the electronic components from being affected by unexpected temperatures. The goal of extending the lifetime and maintaining reliability of the electronic components is achieved.

One embodiment of the present disclosure provides a charging device connected to a charging connector comprises a control module and a temperature control module. The control module is communicatively connected to a plurality of sensing units for receiving at least one sensing signal from the sensing units and generating a pre-action signal based on the at least one sensing signal. The temperature control module is electrically connected to the control module for receiving the pre-action signal. The temperature control module is, according to the pre-action signal, before the charging device executing a charging procedure, to executes a temperature pre-adjustment procedure on the charging device and the charging connector through a dielectric liquid pipeline to adjust the temperatures of the charging device and the charging connector.

One embodiment of the present disclosure provides a charging system comprising a plurality of sensing units, a charging connector and a charging device. The charging device is communicatively connected to a plurality of sensing units. The charging device is connected to the charging connector through a dielectric liquid pipeline. The charging device is used to receive at least one sensing signal, and before executing a charging procedure, according to the at least one sensing signal, to execute a temperature pre-adjustment procedure on the charging device and the charging connector through a dielectric liquid pipeline to adjust the temperatures of the charging device and the charging connector.

In the embodiments of the present disclosure, the charging device and the charging system can detect whether an electric vehicle enters a charging parking space and approaches the charging device through sensing units and execute a temperature pre-adjustment procedure before the charge hole of the electric vehicle to be connected to the charging connector. Thus, the charging device and the charging system can be cooled or heated in advance, and the charging device and the charging system can operate at an appropriate temperature during the charging procedure. It is prevented that the electronic components affected by the unexpected temperatures which is caused by the charging procedure of the charging device and the charging system that is operated at unexpected temperatures. Therefore, the effect that to extend the lifetime and the maintain reliability of the electronic components is achieved.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a charging system in an embodiment of the present disclosure.

FIG. 2 is a schematic diagram of a charging device in an embodiment of the present disclosure.

FIG. 3 is a schematic diagram of a power cabinet in an embodiment of the present disclosure.

FIG. 4 is another schematic diagram of the charging system in the embodiment of the present disclosure.

FIG. 5 is a schematic diagram of an operation method of the charging system in an embodiment of the present disclosure.

FIG. 6 is another schematic diagram of the operation method of the charging system in the embodiment of the present disclosure.

FIG. 7 is another schematic diagram of the operation method of the charging system in the embodiment of the present disclosure.

### DETAILED DESCRIPTION OF THE INVENTION

The present invention will now be described more fully hereinafter with reference to the accompanying drawings, in which exemplary embodiments of the invention are shown. This present invention may, however, be embodied in many different forms and should not be construed as limited to the embodiments set forth herein. Rather, these embodiments are provided so that this present invention will be thorough and complete, and will fully convey the scope of the present invention to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the invention. This description is made for the purpose of illustration of the general principles of the invention and should not be taken in a limiting sense. The scope of the invention is best determined by reference to the appended claims.

Moreover, the terms “include”, “contain”, and any variation thereof are intended to cover a non-exclusive inclusion. Therefore, a process, method, object, or device that comprises a series of elements not only include these elements, but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

In the following embodiment, the same reference numerals are used to refer to the same or similar elements throughout the invention.

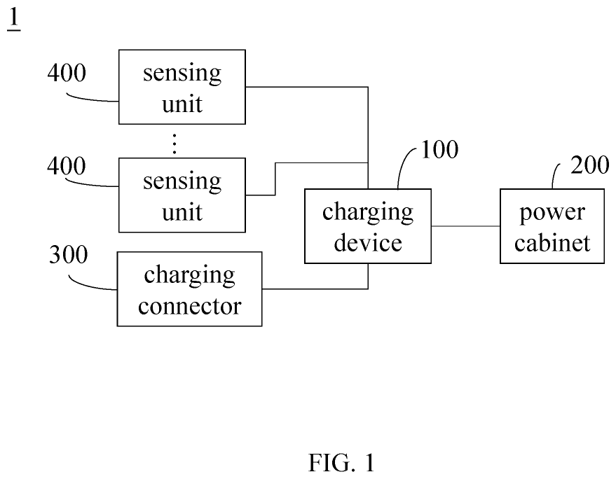

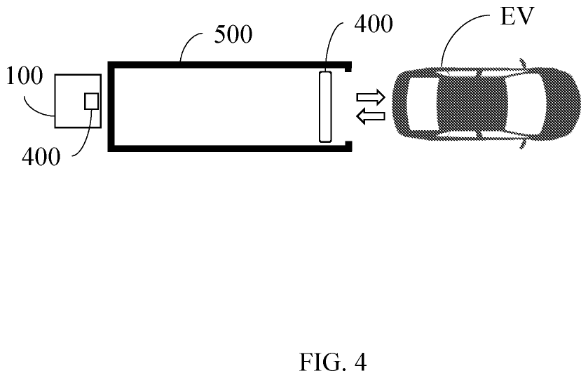

Please refer to FIGS. 1 and 4. FIG. 1 is a schematic diagram of a charging system in an embodiment of the present disclosure. FIG. 4 is another schematic diagram of the charging system in the embodiment of the present disclosure. The charging system 1 comprises a charging device 100, a power cabinet 200, a charging connector 300 and a plurality of sensing units 400.

The charging device 100 is configured to electrically connected to the power cabinet 200 and the sensing units 400. The charging device 100 is configured to connected to the charging connector 300 through a dielectric liquid pipeline and a power cable. The sensing units 400 are configured to generate a plurality of sensing signals. The sensing signals is used to identify whether an electric vehicle EV is entering into a charging parking space 500 and approaching to the charging device 100.

The charging connector 300 is used to contact and connect with a charging hole of the electric vehicle EV. After the communication and power connection between the charging connector 300 and the electric vehicle EV is established through the charging hole, the charging connector 300 provides charging electric energy to the electric vehicle EV according to the charging demand of the electric vehicle EV. In one embodiment, the charging connector 300 is a charging gun.

The power cabinet 200 is configured to connected to the utility power and stores the electric energy required by the charging device 100. The charging device 100 is configured to receive at least one sensing signal from the sensing units. Based on the at least one sensing signal, the charging device 100 executes a temperature pre-adjustment procedure on the charging device 100 and on the charging connector 300 through the dielectric liquid pipeline before the charging power is provided to the electric vehicle EV. Therefore, the temperature of the charging device 100 and the charging connector 300 can be pre-adjusted before the charging procedure.

In the embodiment of the present disclosure, the charging device 100 is a charging pile.

In the embodiment of the present disclosure, the sensing units 400 comprise a near field sensor, a weight sensor and/or a muzzle sensor.

When one of the sensing units 400 is the near field sensor, the near field sensor is disposed at a position where the charging device 100 faces the charging parking space 500 (as shown in FIG. 4). When the near field sensor senses an electric vehicle EV being entering into the charging parking space 500, the near field sensor generates a corresponding sensing signal according to the signal reflected by the electric vehicle EV. The sensing signal is used to identify that an object is approaching to the charging device 100. In one embodiment, the near-field sensor may be an infrared sensor or an ultrasonic sensor, and the present disclosure is not limited thereto.

When one of the sensing units 400 is a weight sensor, the weight sensor is disposed in the charging parking space 500 and adjacent to the side where the electric vehicle EV enters the charging parking space 500 (as shown in FIG. 4). When the electric vehicle EV is driving into the charging parking space 500, the electric vehicle EV presses on the weight sensor. The weight sensor therefore generates a corresponding sensing signal, and the sensing signal is used to identify an object has entered into the charging parking space 500. In one embodiment, the weight sensor may be a pressure sensor or a weighing sensor, and the present disclosure is not limited thereto.

When one of the sensing units 400 is a muzzle sensor, the muzzle sensor is disposed in the charging connector holder of the charging device 100. When the charging connector 300 is extracted from the charging connector holder and the charging connector 300 is not in contact with the muzzle sensor, the sensing unit 400 generates a corresponding sensing signal. The sensing signal is used to identify that the charging connector 300 has been extracted. In one embodiment, the muzzle sensor may be a reed or a contact sensor, and the present disclosure is not limited thereto.

In the embodiment, the sensing units 400 are electrically connected to the charging device 100 in a wired or wireless communication manner. For example, the sensing units 400 are electrically connected to the charging device 100 through communication protocols such as RS232 protocol, Ethernet protocol, Bluetooth protocol, and Wireless LAN protocol.

In the embodiment, the temperature pre-adjustment procedure comprises a cooling procedure and a heating procedure. When the temperature pre-adjustment procedure is a cooling procedure, the charging device 100 can pre-cool the charging device 100 and the charging connector 300 before the charging procedure is started. Therefore, when the charging device 100 and the charging connector 300 are operating in the charging procedure, the high temperature generated by the charging procedure can be quickly cooled down due to the cooling procedure implemented on the charging device 100 and the charging connector 300. The temperatures of the charging device 100 and the charging connector 300 can be maintained at an appropriate operating temperature during the charging procedure. When the temperature pre-adjustment procedure is a heating procedure, the charging device 100 and the charging connector 300 can be pre-heated before the charging procedure is started. Therefore, the charging device 100 and the charging connector 300 are prevented from executing the charging procedure at low temperature. The temperatures of the charging device 100 and the charging connector 300 can be maintained at an appropriate operating temperature during the charging procedure. Therefore, the charging system embodiment of the present disclosure can prevent the charging device 100 and the charging system 1 from executing the charging procedure at unexpected temperatures (high or low temperatures), and the effect of extending the life of electronic components and maintaining reliability of the charging system 1 are obtained.

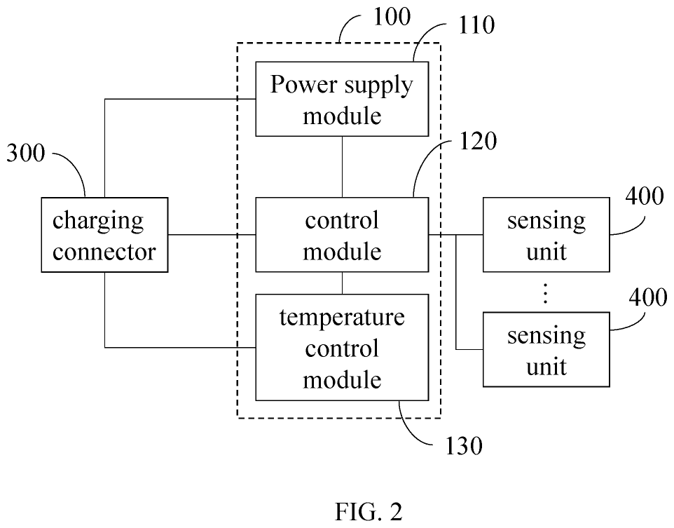

Please refer to FIG. 2. FIG. 2 is a schematic diagram of a charging device in an embodiment of the present disclosure. In the embodiment, the charging device 100 comprises a power supply module 110, a control module 120 and a temperature control module 130. The control module 120 is electrically connected to the power supply module 110 and the temperature control module 130. The power supply module 110 is electrically connected to the charging connector 300 to provide charging power to the charging connector 300.

The control module 120 is electrically connected to the sensing units 400 for receiving at least one sensing signal from the sensing units 400. The control module 120 is configured to generate the pre-action signal based on the at least one sensing signal.

In one embodiment, when the control module 120 determines that the electric vehicle EV is driving into the charging parking space 500 for charging based on the received sensing signal of the near-field sensor and the sensing signal of the weight sensor, the control module 120 generates the pre-action signal. In this embodiment, before the charging procedure is executed, the charging device 100 can sense the presence of the electric vehicle EV through the sensing signals of the sensing units 400 and executes the temperature pre-adjustment procedure. Therefore, rapid temperature changes of the charging device 100 and the charging connector 300 due to the charging procedure can be avoided. It is effectively avoided that the charging device 100 and the charging system 1 execute the charging procedure at unexpected temperatures (high temperature or low temperature).

In one embodiment, when the control module 120 determines that the electric vehicle EV is entering into the charging parking space 500 for charging based on the sensing signals of a plurality of weight sensors, the control module 120 generates the pre-action signal. In the embodiment, the front wheels and rear wheels of the electric vehicle EV pass on the weight sensor respectively when the electric vehicle EV is entering into the charging parking space 500. When the control module 120 determines that it has received two sensing signals from the weight sensor continuously, it means that the electric vehicle EV has entered the charging parking space 500.

In one embodiment, when the control module 120 determines that the electric vehicle EV has entered the charging parking space 500 for charging based on the sensing signal of the muzzle sensor, the control module 120 generates the pre-action signal. In the embodiment, since the sensing signal of the muzzle sensor is used to identify that the charging connector 300 has been extracted, it represents that the electric vehicle EV is ready for charging.

In an embodiment, when the near-field sensor and the weight sensor fail, the muzzle sensor can be used as an auxiliary mechanism to enable the charging device 100 to execute the temperature pre-adjustment procedure before the charging procedure is executed. Therefore, it is effectively avoided that the charging device 100 and the charging system 1 execute the charging procedure at unexpected temperatures.

The control module 120 is configured to receive a connection notification signal and a charging demand information from the charging connector 300, and the control module 120 generates an action signal based on the connection notification signal. Based on the charging demand information, the control module 120 enables the power supply module 110 to execute the charging procedure.

In the embodiment, the control module 120 is a control motherboard including a microprocessor, a communication circuit, and a memory, and the present disclosure is not limited thereto. In one embodiment, the communication circuit of the control module 120 can comply with communication protocols such as RS232 protocol, Ethernet protocol, Bluetooth protocol, and Wireless LAN protocol, and the present disclosure is not limited thereto.

The temperature control module 130 is connected to the dielectric liquid pipelines provided in the charging device 100 and the charging connector 300. The temperature control module 130 is configured to receive the pre-action signal. Based on the pre-action signal received, the temperature control module 130 executes the temperature pre-adjustment procedure on the charging device 100 and the charging connector 300 through the dielectric liquid pipeline before the charging procedure. Therefore, temperatures of the charging device 100 and the charging connector 300 can be pre-adjusted. In the embodiment, during the temperature pre-adjustment procedure, the temperature control module 130 operates in a non-full load mode. In one embodiment, during the temperature pre-adjustment procedure, the temperature control module 130 drives the dielectric liquid flow in the dielectric liquid pipelines based on the pre-action signal. Therefore, the temperature of the charging device 100 and the charging connector 300 can be cooled or heated by the dielectric liquid flowing in the dielectric liquid pipeline.

The temperature control module 130 also receives the action signal. Based on the action signal, the temperature control module 130 executes a temperature adjustment process on the charging device 100 and the charging connector 300 through the dielectric liquid pipeline during the charging procedure. In the embodiment, during the temperature adjustment process, the temperature control module 130 operates in a full load mode to effectively maintain the temperatures of the charging device 100 and the charging connector 300 during the charging procedure.

In the embodiment, if the charging device 100 and the charging connector 300 have not yet been operated in the charging procedure, there is no need to quickly stabilize the temperatures of the charging device 100 and the charging connector 300. Thus, by operating the temperature control module 130 in the non-full load mode instead of the full-load mode during the temperature pre-adjustment procedure, the charging device 100 and the charging connector 300 can be pre-cooled or heated with lower power consumption, and the effect of maintaining the temperature of the charging device 100 and the charging connector 300 during the charging procedure can be achieved by the temperature pre-adjustment procedure.

In the embodiment, the temperature control module 130 is a cooling distribution unit (CDU), and the present disclosure is not limited thereto.

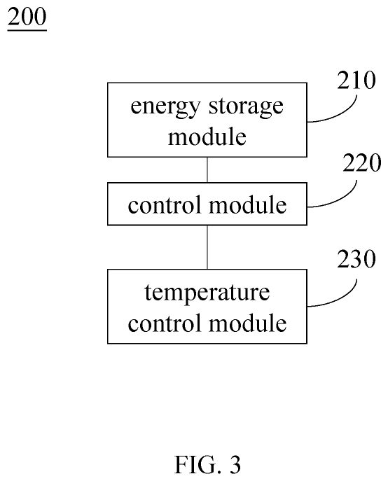

Please refer to FIG. 3. FIG. 3 is a schematic diagram of a power cabinet in an embodiment of the present disclosure. In the embodiment, the power cabinet 200 comprises an energy storage module 210, a control module 220 and a temperature control module 230. The control module 220 is electrically connected to the energy storage module 210 and the temperature control module 230. The energy storage module 210 is electrically connect with the utility power and the power supply module 110 of the charging device 100. The energy storage module 210 is configured to store electrical energy and provide the electrical energy required by the charging device 100. In one embodiment, the control module 220 is communicatively connected with the control module 120 of the charging device 100 for receiving the pre-action signal from the charging device 100 and enables the temperature control module 230 based on the pre-action signal. The temperature control module 230 is connected to a dielectric liquid pipeline provided in the power cabinet 200. The temperature control module 230 is configured to receive the pre-action signal from the charging device 100 and based on the pre-action signal to execute the temperature pre-adjustment procedure that is corresponding to the temperature pre-adjustment procedure of the charging device 100. Therefore, the temperature of the power cabinet 200 can be pre-adjusted.

In the embodiment, the control module 220 is a control motherboard including a microprocessor, a communication circuit, and a memory, and the present disclosure is not limited thereto. In one embodiment, the communication circuit of the control module 220 can comply with communication protocols such as RS232 protocol, Ethernet protocol, Bluetooth protocol, and Wireless LAN protocol, and the present disclosure is not limited thereto. Therefore, the control module 220 can establish a communication connection with the control module 120 of the charging device 100 and receive signals from the control module 120.

Accordingly, when an electric vehicle EV is entering into the charging parking space 500 and approaching to the charging device 100, the electric vehicle EV can be sensed through the sensing units 400 of the charging device 100 and the charging system 1. The temperature pre-adjustment procedure is executed in advance before the charging connector 300 is connecting to the charging hole of the electric vehicle EV. Thereby, the temperature of the charging device 100 and the charging system I can be cooled or heated in advance, so that the charging device 100 and the charging system I can operate at an appropriate temperature during the charging procedure. It prevents the charging device 100 and the charging system 1 from executing the charging procedure at an unexpected temperature and causing the electronic components damaged. Thereby, the life of the electronic components and maintaining reliability is extended.

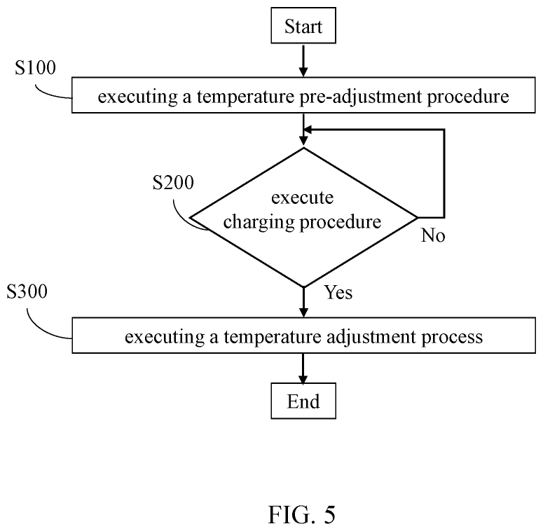

Please refer to FIGS. 1 and 5. FIG. 5 is a schematic diagram of an operation method of a charging system in an embodiment of the present disclosure.

In step S100, executing a temperature pre-adjustment procedure, the charging device 100 executes the temperature pre-adjustment procedure on the charging device 100 and the charging connector 300. In one embodiment, the power cabinet 200 also execute a temperature pre-adjustment procedure.

In step S200, the charging device 100 determines whether the connection notification signal and the charging demand information from the charging connector 300 are received. When the connection notification signal and the charging demand information from the charging connector 300 are received, the charging device 100 executes the charging procedure; otherwise, the charging procedure is not executed. The charging device 100 continuously detects for the connection notification signal and the charging demand information.

In step S300, if the charging device 100 is ready to execute the charging procedure, the charging device 100 executes a temperature adjustment process to maintain the temperatures of the charging device 100 and the charging connector 300 during the charging procedure.

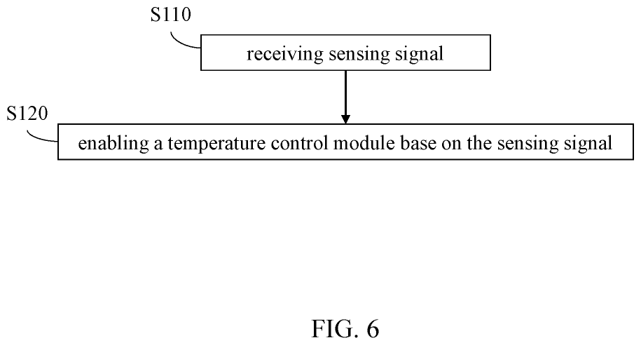

As shown in FIG. 6, step S100 further includes the following steps S110-S120.

In step S110, the control module 120 of the charging device 100 receives sensing signals from the sensing units 400.

In step S120, the control module 120 generates the pre-action signal based on the at least one sensing signal and transmits the pre-action signal to the temperature control module 130 to enable the temperature control module 130 to execute the temperature pre-adjustment procedure. In one embodiment, the control module 120 also transmits the pre-action signal to the power cabinet 200, so that the power cabinet 200 executes a temperature pre-adjustment procedure.

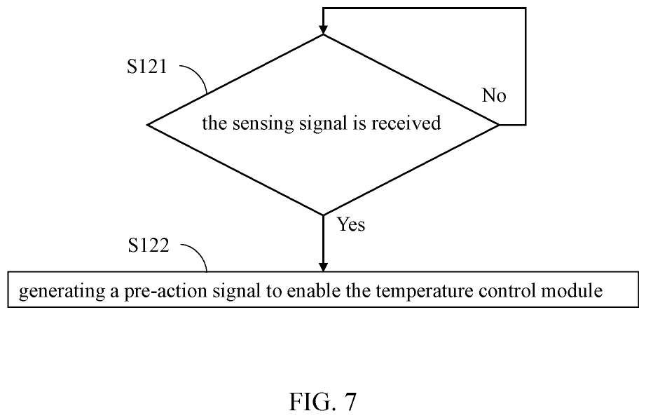

As shown in FIG. 7, step S120 further includes the following steps S121-S122.

In the step S121, the control module 120 determines whether the sensing signal of the near-field sensor and the sensing signal of the weight sensor are received, whether a plurality of sensing signals of the weight sensor are received and/or whether the sensing signal of the muzzle sensor is received. When the control module 120 determines that the sensing signal(s) is (are) received, the step S121 may be executed, otherwise, the step 122 may be executed.

In step S122, the control module 120 generates the pre-action signal according to the determination of step S121, and the control module 120 transmits the pre-action signal to the temperature control module 130 to enable the temperature control module 130 to execute the temperature pre-conditioning procedure.

According to above description, the charging device and the charging system of the present disclosure can sense whether an electric vehicle is entering into the charging parking space and approaches to the charging device through the sensing units. The charging device and the charging system execute a temperature pre-adjustment procedure before the charging connector connects to the charging hole. Therefore, the temperature of the charging device and the charging system can be cooled or heated in advance, and the charging device and the charging system can operate at an appropriate temperature during the charging procedure. The charging device and the charging system can be prevented from executing the charging procedure at unexpected temperatures. The electronic components of the charging system would not be affected by unexpected temperatures. The life of electronic components and maintaining reliability is extended.

It is to be understood that the term “comprises”, “comprising”, or any other variants thereof, is intended to encompass a non-exclusive inclusion, such that a process, method, article, or device of a series of elements not only include those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present invention has been explained in relation to its preferred embodiment, it does not intend to limit the present invention. It will be apparent to those skilled in the art having regard to this present invention that other modifications of the exemplary embodiments beyond those embodiments specifically described here may be made without departing from the spirit of the invention. Accordingly, such modifications are considered within the scope of the invention as limited solely by the appended claims.

1. A charging device connected to a charging connector, comprising:
a control module communicatively connected to a plurality of sensing units for receiving at least one sensing signal from the sensing units and generating a pre-action signal based on the at least one sensing signal; and
a temperature control module electrically connected to the control module for receiving the pre-action signal, and according to the pre-action signal, before the charging device executing a charging procedure, the temperature control module executes a temperature pre-adjustment procedure on the charging device and the charging connector through a dielectric liquid pipeline to adjust the temperatures of the charging device and the charging connector.

2. The charging device according to claim 1, wherein the temperature control module is configured to execute the temperature pre-adjustment procedure on the charging device and the charging connector in a non-full load mode before the charging device executes the charging procedure.

3. The charging device according to claim 1, wherein the control module is configured to transmit the pre-action signal to a power cabinet and to enable the power cabinet to execute the temperature pre-adjustment procedure on the power cabinet before the charging device executes the charging procedure.

4. The charging device according to claim 1, wherein the sensing units comprise a muzzle sensor disposed in a charging connector holder of the charging device.

5. The charging device according to claim 4, wherein the sensing units comprise a near field sensor and a weight sensor.

6. The charging device according to claim 5, wherein the near field sensor is disposed in the charging device.

7. The charging device according to claim 5, wherein the weight sensor is disposed in a charging parking space corresponding to the charging device.

8. The charging device according to claim 5, wherein the near field sensor comprises an infrared sensor and an ultrasonic sensor.

9. The charging device according to claim 5, wherein the weight sensor comprises a pressure sensor and a weighing sensor.

10. The charging device according to claim 5, wherein the control module generates the pre-action signal based on sensing signals of the near field sensor and the weight sensor.

11. The charging device according to claim 5, wherein the control module generates the pre-action signal based on sensing signals from a plurality of weight sensors.

12. The charging device according to claim 5, wherein the control module generates the pre-action signal based on a sensing signal of the muzzle sensor.

13. The charging device according to claim 1, wherein the temperature pre-adjustment procedure comprises a cooling procedure and a heating procedure.

14. A charging system, comprising:
a plurality of sensing units;
a charging connector; and
a charging device connected to the plurality of sensing units and the charging connector through a dielectric liquid pipeline for receiving at least one sensing signal from the sensing units, and according to the at least one sensing signal, before executing a charging procedure, the charging device executes a temperature pre-adjustment procedure on the charging device and the charging connector through a dielectric liquid pipeline to adjust the temperatures of the charging device and the charging connector.

15. The charging system according to claim 14 further comprising a power cabinet connected to the charging device, and the power cabinet is configured to execute the temperature pre-adjustment procedure on the power cabinet before the charging device executes the charging procedure.
